(19) United States
(12) Patent Application Publication
(10) Pub. No.: US 2022/0016651 A1
(43) Pub. Date: Jan. 20, 2022

(54) SUBSTRATE CLEANING DEVICES, SUBSTRATE PROCESSING APPARATUS, SUBSTRATE CLEANING METHOD, AND NOZZLE

(71) Applicant: EBARA CORPORATION, Tokyo (JP)

(72) Inventors: Fumitoshi Oikawa, Tokyo (JP); Koichi Fukaya, Tokyo (JP); Hisajiro Nakano, Tokyo (JP)

(21) Appl. No.: 17/374,583

(22) Filed: Jul. 13, 2021

(30) Foreign Application Priority Data
Jul. 15, 2020 (JP) 2020-121115

(51) Int. Cl. B05B 7/04; B08B 3/02; B08B 15/02

(52) U.S. Cl. CPC B05B 7/0475; B08B 15/02; B08B 3/02

(57) ABSTRACT

According to one embodiment, provided is a substrate cleaning device including a nozzle that includes: a first supply port; a second supply port; a third supply port; a first discharge port; and a third discharge port, wherein the substrate cleaning device is configured to clean a substrate with jets of the second mixed fluid of the gas, the treatment liquid and the surface tension reducing gas.

### CROSS-REFERENCE TO RELATED APPLICATIONS

This application claims the benefit of Japanese Priority Patent Application JP 2020-121115 filed on Jul. 15, 2020, the entire contents of which are incorporated herein by reference.

### FIELD

The present disclosure relates to substrate cleaning devices, a substrate processing apparatus, a substrate cleaning method, and a nozzle.

### BACKGROUND

Two-fluid jet cleaning devices that perform cleaning (two-fluid jet cleaning) on a substrate with two-fluid jets of ultrapure water (DIW) and nitrogen gas are widely known. When a two-fluid jet cleaning device supplies two-fluid jets onto a substrate, a radial flow along the substrate surface and splashes not along the substrate surface are generated, and the former mainly contributes to substrate cleaning. Therefore, to improve cleaning performance, the radial flow along the substrate surface may be increased, and the splashes not along the substrate surface may be reduced.

To enhance the ability to remove particles adhering to a substrate, the speed of collision of droplets with the substrate may be increased. However, if the collision speed is too high, the substrate might be damaged. Particularly, miniaturization of devices formed on substrates has progressed recently, and even the smallest defects are not allowed. Further, if the collision speed is increased, the requisite values of the supply source pressure and the supply flow rate of gas and liquid required by a two-fluid jet cleaning device also become higher, which is not efficient from the viewpoint of energy saving.

Therefore, it is effective to reduce the splashes not traveling along the substrate surface. The cause of the splashes is the surface tension of ultrapure water. Therefore, a substrate is cleaned with a fluid to which isopropyl alcohol (IPA) having the effect of reducing the surface tension of ultrapure water is added.

For example, Patent Document 1 (Japanese Patent No. 4011900) discloses a technique by which nitrogen gas and IPA are first mixed, ultrapure water is then mixed with them, and substrate cleaning is performed with the resultant fluid. Patent Document 1 also discloses a technique by which ultrapure water and IPA are first mixed, nitrogen gas is then mixed with them, and substrate cleaning is performed with the resultant fluid.

Patent Document 2 (Japanese Patent No. 4349606) discloses a technique for cleaning a substrate with a fluid formed with a treatment liquid, nitrogen gas, and IPA in a liquid state.

### SUMMARY

According to one embodiment, provided is a substrate cleaning device comprising a nozzle that comprises: a first supply port connected to a treatment liquid supplier configured to supply a treatment liquid; a second supply port connected to a gas supplier configured to supply a gas; a third supply port connected to a surface tension reducing gas supplier configured to supply a surface tension reducing gas for reducing surface tension of the treatment liquid; a first discharge port configured to discharge the treatment liquid; a second discharge port configured to discharge the gas, so as to mix the gas and the treatment liquid discharged from the first discharge port to generate a first mixed fluid at a first mixing position; and a third discharge port configured to discharge the surface tension reducing gas, so as to mix the first mixed fluid and the surface tension reducing gas to generate a second mixed fluid at a second mixing position, the second mixing position being farther away from the first discharge port than the first mixing position, wherein the substrate cleaning device is configured to clean a substrate with jets of the second mixed fluid.

According to one embodiment, provided is a substrate cleaning device comprising a nozzle in which a first flow path, a second flow path and a third flow path are provided, the first flow path being connected to a treatment liquid supplier configured to supply a treatment liquid; the second flow path being connected to a gas supplier configured to supply a gas; and the third flow path being configured to a surface tension reducing gas supplier configured to supply a surface tension reducing gas for reducing surface tension of the treatment liquid, wherein the first flow path, the second flow path, and the third flow path are configured such that the treatment liquid discharged from the first flow path and the gas discharged from the second flow path are mixed at a first mixing position to generate a first mixed fluid, and the first mixed fluid and the surface tension reducing gas discharged from the third flow path are mixed at a second mixing position to generate a second mixed fluid, the second mixing position being located on a downstream side of the first mixing position in a flow of the first mixed fluid, and the substrate cleaning device is configured to clean a substrate with jets of the second mixed fluid.

According to one embodiment, provided is a substrate cleaning device comprising a nozzle in which a first flow path, a second flow path, a third flow path and a fourth path are provided, the first flow path being connected to a treatment liquid supplier configured to supply a treatment liquid; the second flow path being connected to a gas supplier configured to supply a gas; the third flow path being connected to a surface tension reducing gas supplier configured to supply a surface tension reducing gas for reducing surface tension of the treatment liquid; and the fourth flow path being joined to the first flow path and the second flow path, a first mixed fluid flowing through the fourth flow path, the first mixed fluid being a mixture of the treatment liquid and the gas, wherein the third flow path and the fourth flow path are configured such that the first mixed fluid discharged from the fourth flow path and the surface tension reducing gas discharged from the third flow path are mixed to generate a second mixed fluid, and the substrate cleaning device is configured to clean a substrate with jets of the second mixed fluid.

According to one embodiment, provided is a substrate cleaning device comprising a nozzle that comprises in the nozzle in which a first flow path, a second flow path, a third flow path and a fourth path are provided, the first flow path being connected to a treatment liquid supplier configured to supply a treatment liquid; the second flow path being connected to a gas supplier configured to supply a gas; the third flow path being connected to a surface tension reducing gas supplier configured to supply a surface tension reducing gas for reducing surface tension of the treatment liquid; and the fourth flow path being joined to the first flow path, the second flow path, and the third flow path, wherein the first to fourth flow paths are configured such that the treatment liquid discharged from the first flow path and the gas discharged from the second flow path are mixed at a first mixing position to generate a first mixed fluid in the fourth flow path, and the first mixed fluid and the surface tension reducing gas discharged from the third flow path are mixed at a second mixing position to generate a second mixed fluid in the fourth flow path, the second mixing position being located on a downstream side of the first mixing position in a flow of the first mixed fluid, and the substrate cleaning device is configured to clean a substrate with jets of the second mixed fluid.

The substrate cleaning device may further comprise: a gasifier configured to gasify a surface tension inhibitor in a liquid state, to generate the surface tension reducing gas.

The gasifier may be configured to gasify the surface tension inhibitor in a liquid state by an injection technique, to generate the surface tension reducing gas.

The gasifier may be of a baking type, of a bubbling type, or a vaporizer.

The substrate cleaning device may further comprise: a filter through which the surface tension reducing gas passes, wherein the surface tension reducing gas having passed through the filter may be mixed with the first mixed fluid.

The substrate cleaning device may further comprise: a cleaning fluid supplier configured to supply the treatment liquid to the nozzle at 200 to 400 ml/min.

The substrate cleaning device may further comprise: a cleaning fluid supplier that supplies the gas to the nozzle at 100 to 200 SLM.

The treatment liquid may be ultrapure water or carbon-dioxide-containing water, the gas may be an inert gas or dry air, and the surface tension reducing gas may be an IPA gas.

The inert gas may be a nitrogen gas.

A concentration of the IPA gas in the second mixed fluid, or a total concentration of the IPA gas and the nitrogen gas in the second mixed fluid may be 10 to 30%.

According to one embodiment, provided is a the substrate processing apparatus comprising: a substrate polishing device configured to polish a substrate; and the above substrate cleaning device configured to clean the polished substrate.

According to one embodiment, provided is a substrate cleaning method comprising: mixing a treatment liquid and a gas to generate a first mixed fluid; mixing a surface tension reducing gas for reducing surface tension of the treatment liquid and the first mixed fluid to generate a second mixed fluid, after the first mixed fluid is generated; and cleaning a substrate by emitting jets of the second mixed fluid onto the substrate.

According to one embodiment, provided is a nozzle used for a substrate cleaning device, a first flow path, a second flow path, a third flow path and a fourth flow path are provided in the nozzle, the first flow path comprising a first inlet and a first outlet, the first inlet being open toward an outer surface of the nozzle, the first outlet being provided inside the nozzle; the second flow path that comprising a second inlet and a second outlet, the second inlet being open toward the outer surface of the nozzle, the second outlet being provided inside the nozzle; the third flow path that comprising a third inlet and a third outlet, the third inlet being open toward the outer surface of the nozzle, the third outlet being open toward a bottom surface of the nozzle; and the fourth flow path that comprising a fourth inlet and a fourth outlet, the fourth inlet being joined to the first outlet and the second outlet inside the nozzle, the fourth outlet being open toward the bottom surface of the nozzle, wherein the fourth flow path is located substantially at a center of the nozzle, and a diameter of the fourth flow path at least in a vicinity of the fourth outlet is larger at a location closer to the bottom surface of the nozzle, and the third flow path is located radially outside the nozzle with respect to the third flow path, and at least a portion of the third flow path in a vicinity of the third outlet is more inclined to the center of the nozzle at a location closer to the bottom surface of the nozzle.

### BRIEF DESCRIPTION OF DRAWINGS

FIG. 1 is a schematic configuration diagram of a substrate processing apparatus that includes substrate cleaning devices according to an embodiment;

FIG. 2A is a schematic configuration diagram of a substrate cleaning device according to an embodiment;

FIG. 2B is a top view of the relevant parts of the substrate cleaning device;

FIG. 3 is a schematic configuration diagram of a cleaning fluid supply device;

FIG. 4A is a schematic cross-sectional view of a nozzle;

FIG. 4B is a diagram schematically illustrating states in which a fluid flows in the nozzle shown in FIG. 4A;

FIG. 4C is a schematic cross-sectional view of a nozzle that is a modification of the nozzle shown in FIG. 4A;

FIG. 5A is a schematic cross-sectional view of a nozzle that is a modification of the nozzle shown in FIG. 4A;

FIG. 5B is a diagram schematically illustrating states in which a fluid flows in the nozzle shown in FIG. 5A;

FIG. 6A is a schematic cross-sectional view of a nozzle that is a modification of the nozzle shown in FIG. 4A;

FIG. 6B is a diagram schematically illustrating states in which a fluid flows in the nozzle shown in FIG. 6A; and

FIG. 7 is a substrate cleaning process chart according to an embodiment.

### DESCRIPTION

There is a demand for substrate cleaning devices with high cleaning performance, substrate processing apparatuses including such substrate cleaning devices, and substrate cleaning methods for achieving high cleaning performance. There is also a demand for nozzles to be used in such substrate cleaning devices.

First, the inventors of the present application have conceived the idea that, when cleaning a substrate with an IPA containing fluid, it is preferable to use gaseous IPA, instead of liquid IPA, for the reasons described below.

Normally, liquid IPA contained in a SUS container is supplied from a manufacturer, to prevent explosion and take measures against static electricity. Fe-based fine particles are dissolved from the inner surface of the SUS container, and therefore, IPA contains such fine particles. The fine particles adhere to the substrate during cleaning, and sometimes cause back contamination. This is one of the reasons that it is difficult to sufficiently improve cleaning performance.

It is possible to remove the fine particles by filtering liquid IPA. However, only particles of sizes equal to or larger than the pore size of the filter can be removed, and fine particles smaller than the pore size of the filter are hardly removed.

On the other hand, it is possible to remove fine particles much smaller than the pore size of the filter by filtering gaseous IPA obtained by gasifying liquid IPA. This is because a comparison between liquid IPA and gaseous IPA shows that Brownian motion and inertial motion of fine particles are more active in the latter, and the adhesive force between the fine particles and the filter material is also larger in the latter.

In view of the above facts, gaseous IPA (hereinafter referred to as “IPA gas”) is used for substrate cleaning in the present invention. The IPA gas is also called IPA vapor.

Next, the present inventors have conceived the idea that, when cleaning a substrate with a fluid formed with ultrapure water, nitrogen gas, and IPA, it is preferable to first mix the ultrapure water and the nitrogen gas, and then mix the IPA gas with the resultant fluid. As the ultrapure water and the nitrogen gas are mixed beforehand, the ultrapure water is atomized. Accordingly, the total surface area of the ultrapure water becomes larger, and the IPA gas is easily dissolved in the ultrapure water.

On the other hand, the nitrogen gas and the IPA gas may be mixed first, and the ultrapure water may then be mixed with the resultant fluid. In the case of this mixing order, however, the IPA gas concentration is diluted by the mixing of the nitrogen gas and the IPA gas, and the ultrapure water is then atomized. Therefore, the IPA gas is not sufficiently dissolved in the ultrapure water.

Also, the ultrapure water and IPA may be mixed first, and the nitrogen gas may then be mixed with the resultant fluid. In the case of this mixing order, however, the ultrapure water is not atomized, and the ultrapure water not having a very large total area is mixed with a gas. Therefore, the IPA gas is not sufficiently dissolved in the ultrapure water.

In view of the above facts, the ultrapure water and the nitrogen gas are mixed first, and the IPA gas is then mixed with them in the present invention. The resultant fluid is used for cleaning.

The following is a detailed description of embodiments of the present invention, with reference to the accompanying drawings.

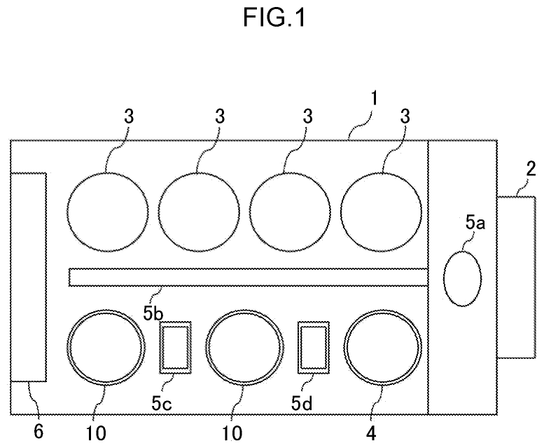

FIG. 1 is a schematic configuration diagram of a substrate processing apparatus that includes substrate cleaning devices 10 according to an embodiment. The substrate processing apparatus processes various kinds of substrates such as semiconductor wafers, flat panels, and image sensors that have a diameter of 300 mm or 450 mm.

The substrate processing apparatus includes a substantially rectangular housing 1, a load port 2 on which a substrate cassette for storing a large number of substrates is placed, one or a plurality of (four in the mode shown in FIG. 1) substrate polishing devices 3, a plurality of (two in the mode shown in FIG. 1) substrate cleaning devices 10, a substrate drying device 4, conveyance mechanisms 5a to 5d, and a controller 6.

The substrate polishing devices 3 polish a substrate loaded from the load port 2. In an exemplary embodiment, a polishing treatment in the substrate polishing devices 3 may be a chemical mechanical polishing treatment (CMP treatment). In another exemplary embodiment, a polishing treatment in the substrate polishing devices 3 may be a bevel polishing treatment or an entire back surface polishing treatment, or may be a process of performing a grinding treatment while the substrate surfaces are kept dry. The substrate cleaning devices 10 clean the polished substrates. In an exemplary embodiment, a substrate to be introduced into a substrate cleaning device 10 is polished by a substrate polishing device 3, is carried out from the substrate polishing device 3 while the substrate surface is kept in a wet state, and is introduced into the substrate cleaning device 10. The substrate drying device 4 dries the cleaned substrates. The conveyance mechanisms 5a to 5d convey the substrates between the respective devices. The controller 6 controls operations of the respective devices of the substrate processing apparatus. The controller 6 may include a memory that stores a predetermined program, a central processing unit (CPU) that executes the program in the memory, and a control module that is formed by the CPU executing the program.

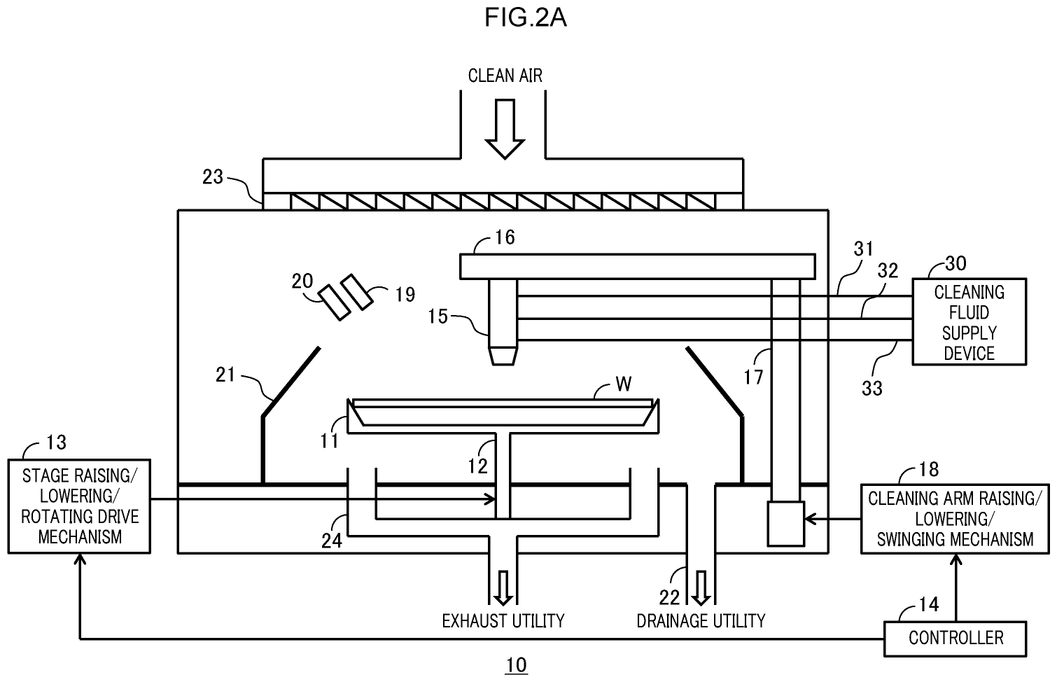

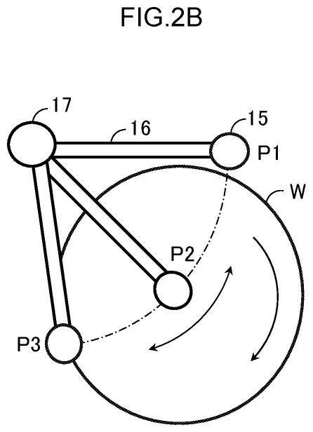

FIG. 2A is a schematic configuration diagram of a substrate cleaning device 10 according to an embodiment. FIG. 2B is a top view of the relevant parts of the substrate cleaning device 10. This substrate cleaning device 10 performs two-fluid jet cleaning, which is substrate cleaning by emitting jets of ultrapure water and nitrogen gas onto a substrate.

As shown in FIG. 2A, the substrate cleaning device 10 includes a spin chuck 11 (a substrate holder), a stage rotation shaft 12, a stage raising/lowering/rotating drive mechanism 13, and a controller 14. Note that this controller 14 may be the controller 6 shown in FIG. 1, or may be provided independently of the controller 6.

The spin chuck 11 holds the cleaning target substrate W in the horizontal direction. The spin chuck 11 is attached to the stage rotation shaft 12 extending in the vertical direction. Accordingly, the substrate W held by the spin chuck 11 rotates in a horizontal plane, in synchronization with rotation of the stage rotation shaft 12. The stage rotation shaft 12 is raised, lowered, or rotated by the stage raising/lowering/rotating drive mechanism 13. The stage raising/lowering/rotating drive mechanism 13 is controlled by the controller 14.

The substrate cleaning device 10 also includes a cleaning fluid supply device 30, a nozzle 15, a cleaning arm 16, a cleaning arm swing shaft 17, a cleaning arm raising/lowering/swinging mechanism 18, a chemical supply mechanism 19, and an ultrapure water supply mechanism 20.

The cleaning fluid supply device 30 supplies a cleaning fluid to the nozzle 15. More specifically, ultrapure water, nitrogen gas, and IPA gas are supplied to the nozzle 15 from an ultrapure water supply pipe 31, a nitrogen gas supply pipe 32, and an IPA gas supply pipe 33, respectively, of the cleaning fluid supply device 30. The nozzle 15 supplies a cleaning fluid containing ultrapure water, nitrogen gas, and IPA gas to the upper surface of the substrate W that rotates. Example configurations of the cleaning fluid supply device 30 and the nozzle 15 will be described later.

The upper end of the nozzle 15 is attached to a portion near an end of the cleaning arm 16. The other end of the cleaning arm 16 is attached to the cleaning arm swing shaft 17 extending in the vertical direction. Accordingly, in synchronization with rotation of the cleaning arm swing shaft 17, the cleaning arm 16 swings about the cleaning arm swing shaft 17, so that the nozzle 15 swings. The cleaning arm swing shaft 17 is raised and lowered, or is swung by the cleaning arm raising/lowering/swinging mechanism 18. The cleaning arm raising/lowering/swinging mechanism 18 is controlled by the controller 14.

The chemical supply mechanism 19 and the ultrapure water supply mechanism 20 supply a chemical liquid and ultrapure water, respectively, to the upper surface of the substrate W that rotates.

As shown in FIG. 2B, when cleaning is not performed, the nozzle 15 is at a retraction position P1. When cleaning is performed, the nozzle 15 swings between a position P2 near the center of the substrate W and a position P3 near the edge of the substrate W (or between positions near the edge on the opposite sides), while emitting the cleaning fluid.

Referring back to FIG. 2A, the substrate cleaning device 10 includes a process cup 21, a drainage pipe 22, a filter/fan unit 23, and an exhaust duct 24.

The process cup 21 covers the sides of the substrate W held by the spin chuck 11. The liquids such as the chemical liquid and the ultrapure water to be used for cleaning are guided to the drainage pipe 22 without scattering to the outside of the process cup 21, and flow into the drainage utility.

Further, the filter/fan unit 23 is disposed on an upper portion of the substrate cleaning device 10, and clean air is guided into the substrate cleaning device 10 via the filter/fan unit 23. The air then flows from the exhaust duct 24 into the drainage utility.

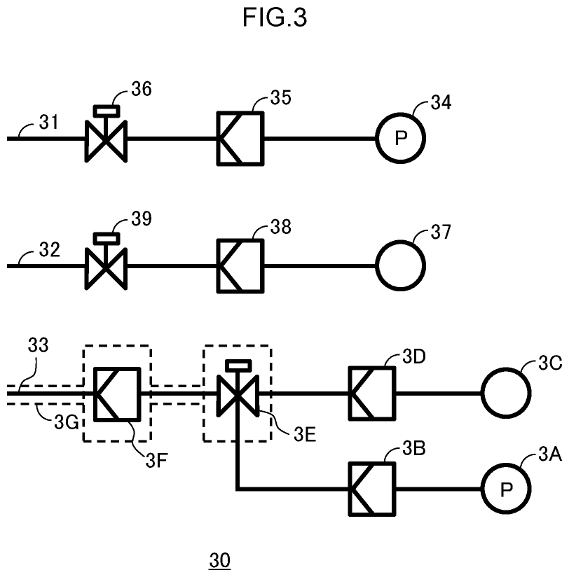

FIG. 3 is a schematic configuration diagram of the cleaning fluid supply device 30.

The cleaning fluid supply device 30 includes an ultrapure water supplier 34, a filter 35, an electromagnetic valve 36, and the ultrapure water supply pipe 31. The ultrapure water from the ultrapure water supplier 34 is supplied from the ultrapure water supply pipe 31 to the nozzle 15 via the filter 35 and the electromagnetic valve 36. As the ultrapure water passes through the filter 35, fine particles in the ultrapure water are removed. The amount of the ultrapure water to be supplied to the nozzle 15 and turning on/off of the supply of the ultrapure water to the nozzle 15 are controlled by the electromagnetic valve 36.

The cleaning fluid supply device 30 also includes a nitrogen gas supplier 37, a filter 38, an electromagnetic valve 39, and the nitrogen gas supply pipe 32. The nitrogen gas from the nitrogen gas supplier 37 is supplied from the nitrogen gas supply pipe 32 to the nozzle 15 via the filter 38 and the electromagnetic valve 39. As the nitrogen gas passes through the filter 38, fine particles in the nitrogen gas are removed. The amount of the nitrogen gas to be supplied to the nozzle 15 and turning on/off of the supply of the nitrogen gas to the nozzle 15 are controlled by the electromagnetic valve 39.

The cleaning fluid supply device 30 further includes a liquid IPA supplier 3A, a filter 3B, a nitrogen gas supplier 3C, a filter 3D, a gasifier 3E, a filter 3F, a heater or heat insulator 3G, and the IPA gas supply pipe 33.

The liquid IPA from the liquid IPA supplier 3A flows into the gasifier 3E via the filter 3B. As the liquid IPA gas passes through the filter 3D, relatively large fine particles in the liquid IPA are removed. More specifically, the liquid IPA contains Fe-based fine particles derived from the container made of SUS as described above. Among such fine particles, the fine particles having almost the same size as the pore size of the filter 3B are removed by the filter 3B. On the other hand, the fine particles smaller than the pore size of the filter 3B pass through the filter 3B, and thus, flow into the gasifier 3E while being contained in the liquid IPA.

Further, the nitrogen gas from the nitrogen gas supplier 3C flows into the gasifier 3E via the filter 3D. As the nitrogen gas passes through the filter 3D, fine particles in the nitrogen gas are removed.

Using the nitrogen gas as the carrier gas, the gasifier 3E then vaporizes the liquid IPA and generates gaseous IPA.

The gaseous IPA is supplied from the IPA gas supply pipe 33 to the nozzle 15 via the filter 3F. As the gaseous IPA gas passes through the filter 3F, small fine particles contained in the gaseous IPA are also removed. When the gaseous IPA does not contain small fine particles, the filter 3F can be omitted.

To prevent the gasified IPA from returning to a liquid, the heater or heat insulator 3G is preferably provided at the portion through which the gaseous IPA passes. The portion includes the gasifier 3E, the filter 3F, the pipe between the gasifier 3E and the filter 3F, and at least part of the IPA gas supply pipe 33.

Note that the configuration of the gasifier 3E is not limited to any particular one. For example, the gasifier 3E may gasify the liquid IPA by a bubbling technique by which nitrogen gas as a carrier gas passes through a liquid layer of a container filled with the liquid IPA, and gaseous IPA is mixed in the nitrogen gas. By the bubbling technique, the concentration of the gaseous IPA in the mixed gas is determined by the saturated vapor pressure, and is about 4% at room temperature.

Also, the gasifier 3E may gasify the liquid IPA by an injection technique by which the liquid IPA is heated beforehand, and the pressure is then lowered. For example, the liquid material gasifier system MV-2000 series manufactured by HORIBA STEC Co., Ltd. can be used as the gasifier 3E. There is also an injection technique (the direct injection VC series manufactured by the same company, for example) that does not use any carrier gas, and in that case, the nitrogen gas supplier 3C and the filter 3D are unnecessary. In the case of an injection technique, the concentration of the gaseous IPA in the mixed gas can be increased to about 20% at room temperature.

Further, a baking technique (the compact baking system LSC series, for example), or a vaporizer (the high-flow-rate vaporizer LE series manufactured by the same company, for example) may be applied as the gasifier 3E.

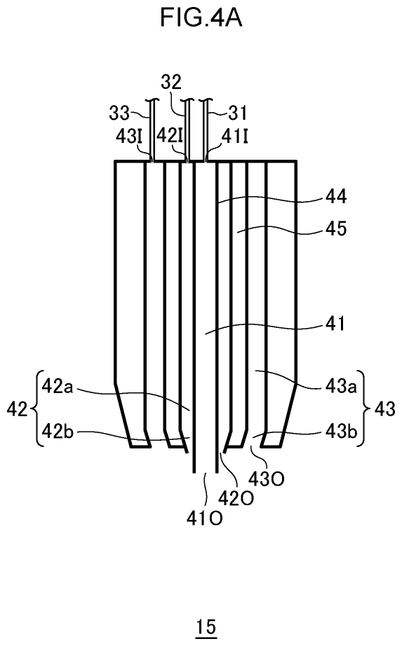

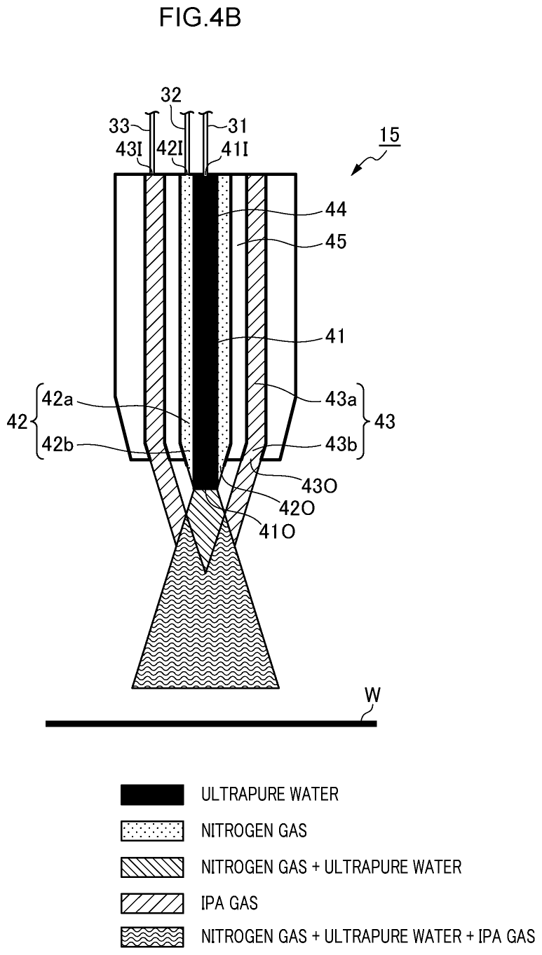

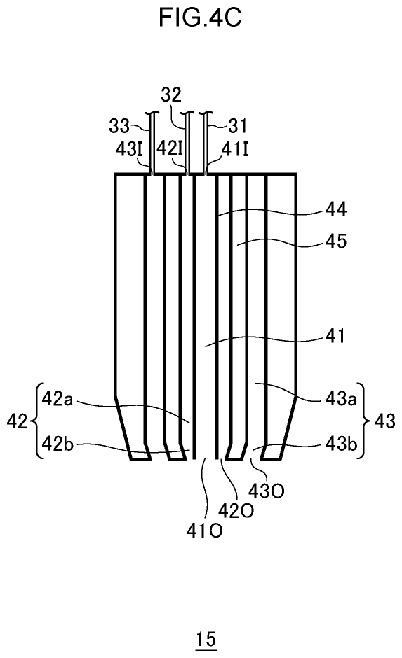

FIG. 4A is a schematic cross-sectional view of the nozzle 15. FIG. 4B is a diagram schematically illustrating states in which a fluid flows in the nozzle 15 shown in FIG. 4A. The nozzle 15 mixes the ultrapure water and the nitrogen gas outside (on the downstream side of) the nozzle 15, and also mixes the mixed fluid and the IPA gas outside (on the downstream side of) the nozzle 15.

The nozzle 15 includes a flow path 41 through which the ultrapure water passes, a flow path 42 through which the nitrogen gas passes, and a flow path 43 through which the IPA gas passes. Further, in the nozzle 15, a sidewall 44 separates the flow path 41 from the flow path 42, and a sidewall 45 separates the flow path 42 from the flow path 43.

The flow path 41 is located almost at the center of the nozzle 15. A cross-section of the flow path 41 in a horizontal direction (a direction parallel to the substrate W) is substantially circular. The flow path 41 extends vertically from the upper surface of the nozzle 15, and reaches the lower surface of the nozzle 15.

An inlet 41I that is the upper end of the flow path 41 is open toward the upper side of the outer surface of the nozzle 15, and an outlet 41O that is the lower end of the flow path 41 is open toward the bottom surface of the nozzle 15. The ultrapure water supply pipe 31 is connected to the inlet 41I of the flow path 41, and the ultrapure water is supplied into the flow path 41 at 200 to 400 ml/min, for example. The ultrapure water then exits from the outlet 41O of the flow path 41. The inlet 41I can also be referred to as a supply port. The same applies to the other inlets.

Outside the flow path 41, the flow path 42 is positioned concentrically with respect to the flow path 41. The flow path 42 has a substantially annular cross-section in a horizontal direction. The flow path 42 has an upper portion 42a extending from the upper surface of the nozzle 15 to a portion in the vicinity of the lower surface of the nozzle 15, and a lower portion 42b extending from the portion in the vicinity of the lower surface to the lower surface of the nozzle 15. The inner surface of the lower portion 42b (on the side of the sidewall 44) extends in a vertical direction. On the other hand, the outer surface of the lower portion 42b (on the side of the sidewall 45) is tapered, and the bottom portion is inclined toward the center of the nozzle 15.

An inlet 42I that is the upper end of the flow path 42 is open toward the upper side of the outer surface of the nozzle 15, and an outlet 42O that is the lower end of the flow path 42 is open toward the bottom surface of the nozzle 15. The nitrogen gas supply pipe 32 is connected to the inlet 42I of the flow path 42, and the nitrogen gas is supplied into the flow path 42 at 100 to 200 SLM (Standard Litter per Minute), for example. The nitrogen gas then exits from the outlet 42O of the flow path 42. The outlet 42O can also be referred to as a discharge port. The same applies to the other outlets.

Outside the flow path 42, the flow path 43 is positioned concentrically with respect to the flow path 42 and the flow path 41. The flow path 43 has a substantially annular cross-section in a horizontal direction. The flow path 43 has an upper portion 43a extending from the upper surface of the nozzle 15 to a portion in the vicinity of the lower surface of the nozzle 15, and a lower portion 43b extending from the portion in the vicinity of the lower surface to the lower surface of the nozzle 15. The bottom portion of the lower portion 43b is inclined toward the center of the nozzle 15. The lower end of the flow path 43 and the lower end of the flow path 42 may be in the same plane.

An inlet 43I that is the upper end of the flow path 43 is open toward the upper side of the outer surface of the nozzle 15, and an outlet 43O that is the lower end of the flow path 43 is open toward the bottom surface of the nozzle 15. The IPA gas supply pipe 33 is connected to the inlet 43I of the flow path 43, and the IPA gas is supplied into the flow path 43. The IPA gas then exits from the outlet 43O of the flow path 43.

In the nozzle 15 having the above configuration, the ultrapure water discharged from the outlet 41O of the flow path 41, and the nitrogen gas discharged from the outlet 42O of the flow path 42 are mixed immediately below the nozzle 15 (at a first mixing position) (see FIG. 4B). As a result, a mixed fluid of the ultrapure water and the nitrogen gas, or more specifically, a fluid in which the ultrapure water is atomized by the nitrogen gas is generated. This fluid does not yet contain the IPA gas.

After that, the mixed fluid and the IPA gas discharged from the outlet 43O of the flow path 43 are mixed above the substrate W (at a second mixing position). The jets of the mixed fluid reach the substrate W, and are used for cleaning. The concentration of the IPA gas (or the total concentration of the nitrogen gas and the IPA gas) in the mixed fluid is preferably about 10% to 30%. Note that the second mixing position is farther away from the outlet 41O than the first mixing position.

The shapes and the like of the nozzle 15 and the flow paths 41 to 43 are not limited to those shown in FIG. 4A. That is, the flow paths 41 to 43 are only required to be designed so that the ultrapure water discharged from the flow path 41 and the nitrogen gas discharged from the flow path 42 are mixed to generate a mixed fluid, and the mixed fluid and the IPA gas discharged from the flow path 43 are mixed to generate a mixed fluid for cleaning.

In FIG. 4A, the outlet 41O of the flow path 41 is at a lower position than the outlet 42O of the flow path 42. In other words, the flow path 41 protrudes from the lower surface of the nozzle 15. In this case, the nitrogen gas flows along the sidewall 44, and accordingly, few components of the nitrogen gas come into contact with the ultrapure water in a direction at an angle close to a right angle. Accordingly, the mixed fluid flows straight, and reaches the substrate W without a significant decrease in speed. Thus, highly adhesive foreign matter can be removed from the substrate W.

However, as shown in FIG. 4C, the outlet 41O of the flow path 41 and the outlet 42O of the flow path 42 may be in the same plane. In this case, the nitrogen gas is discharged into an open space, and therefore, some components come into contact with the ultrapure water in a direction at an angle close to a right angle (a horizontal direction). Therefore, droplets (mist) of the ultrapure water are scattered, and the cleaning liquid can be supplied to a wider region on the substrate W. Thus, foreign matter whose adhesion is not very high can be efficiently removed from the substrate W.

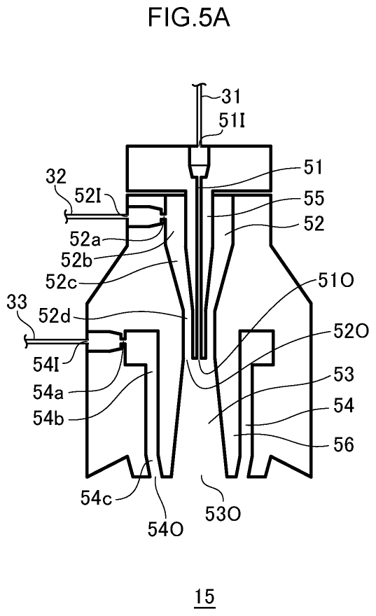

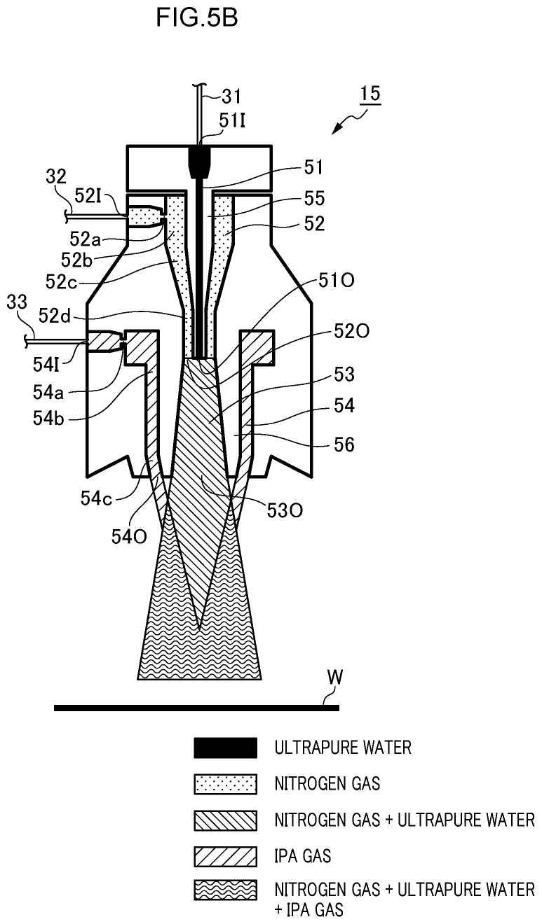

FIG. 5A is a schematic cross-sectional view of a nozzle 15 that is a modification of the nozzle shown in FIG. 4A. FIG. 5B is a diagram schematically illustrating states in which a fluid flows in the nozzle 15 shown in FIG. 5A. The nozzle 15 mixes the ultrapure water and the nitrogen gas in the nozzle 15, and also mixes the mixed fluid and the IPA gas outside (on the downstream side of) the nozzle 15.

The nozzle 15 includes a flow path 51 through which the ultrapure water passes, a flow path 52 through which the nitrogen gas passes, a flow path 53 through which a mixed fluid of the ultrapure water and the nitrogen gas flows, and a flow path 54 through which the IPA gas passes. Further, in the nozzle 15, a sidewall 55 separates the flow path 51 from the flow path 52, and a sidewall 56 separates the flow path 53 from the flow path 54.

The flow path 51 is located almost at the center of the nozzle 15. The flow path 51 has a substantially circular cross-section in a horizontal direction. The flow path 51 extends vertically from the upper surface of the nozzle 15, but does not reach the lower surface of the nozzle 15.

An inlet 51I that is the upper end of the flow path 51 is open toward the upper side of the outer surface of the nozzle 15, but an outlet 51O that is the lower end of the flow path 51 is provided inside the nozzle 15. The ultrapure water supply pipe 31 is connected to the inlet 51I of the flow path 51, and the ultrapure water is supplied into the flow path 51 at 200 to 400 ml/min, for example. The ultrapure water then exits from the outlet 51O of the flow path 51.

The flow path 52 includes a horizontal portion 52a, an upper portion 52b, a middle portion 52c, and a lower portion 52d. The horizontal portion 52a extends in a horizontal direction from the side surface of the nozzle 15, and reaches the side surface of the upper portion 52b. Outside the flow path 51, the upper portion 52b, the middle portion 52c, and the lower portion 52d of the flow path 52 are located concentrically with respect to the flow path 51, and horizontal cross-sections thereof are substantially annular. The upper portion 52b extends in a vertical direction. The middle portion 52c is tapered, and its bottom portion is inclined toward the center of the nozzle 15. The lower portion 52d extends in a vertical direction, but does not reach the lower surface of the nozzle 15. The lower surface (which is an outlet 52O) of the flow path 52 may be substantially in the same plane as the lower surface (which is the outlet 51O) of the flow path 51.

An inlet 52I that is one end of the flow path 52 is open toward the side of the outer surface of the nozzle 15, but the outlet 52O that is the lower end of the flow path 52 is provided inside the nozzle 15. The nitrogen gas supply pipe 32 is connected to the inlet 52I of the horizontal portion 52a, and the nitrogen gas is supplied into the flow path 52 at 100 to 200 SLM, for example. The nitrogen gas then exits from the outlet 52O of the flow path 52.

The flow path 53 is located under the flow path 51 and the flow path 52. The upper end of the flow path 53 is joined to the flow path 51 and the flow path 52. The flow path 53 extends in a vertical direction, and its lower end reaches the lower surface of the nozzle 15. The flow path 53 has a substantially circular cross-section in a horizontal direction. Also, the entire flow path 53 or at least a portion in the vicinity of the lower end spreads out wide toward the end, and the diameter is larger at a portion closer to the lower surface. In the flow path 53 having such a shape, the ultrapure water supplied from the flow path 51, and the nitrogen gas supplied from the flow path 52 are mixed well enough to form a mixed fluid.

An inlet 53I that is the upper end of the flow path 53 is provided inside the nozzle 15, but an outlet 53O that is the lower end of the flow path 53 is open toward the bottom surface of the nozzle 15. At the upper end of the flow path 53, the ultrapure water flows in from the flow path 51, and the nitrogen gas flows in from the flow path 52. A mixed fluid of the ultrapure water and the nitrogen gas then exits from the outlet 53O of the flow path 53.

The flow path 54 includes a horizontal portion 54a, an upper portion 54b, and a lower portion 54c. The horizontal portion 54a extends in a horizontal direction from the side surface of the nozzle 15, and reaches the side surface of the upper portion 54b. Outside the flow path 53, the upper portion 54b and the lower portion 54c of the flow path 54 are located concentrically with respect to the flow path 53, and horizontal cross-sections thereof are substantially annular. The upper portion 54b extends in a vertical direction. The bottom portion of the lower portion 54c is inclined toward the center of the nozzle 15. With such a shape, a mixed fluid of the IPA gas and the mixed fluid of the ultrapure water and the nitrogen gas is quickly formed, and is emitted downward. The lower end of the flow path 54 and the lower end of the flow path 53 may be in the same plane.

An inlet 54I of the flow path 54 is open toward the side of the outer surface of the nozzle 15, but an outlet 54O that is the lower end of the flow path 54 is open toward the bottom surface of the nozzle 15. The IPA gas supply pipe 33 is connected to the inlet 54I, which is one end of the horizontal portion 54a, and the IPA gas is supplied into the flow path 54. The IPA gas then exits from the outlet 54O of the flow path 54.

In the nozzle 15 having the above configuration, the ultrapure water discharged from the outlet 51O of the flow path 51, and the nitrogen gas discharged from the outlet 52O of the flow path 52 are mixed at a predetermined position (a first mixing position) in the flow path 53 (see FIG. 5B). As a result, a mixed fluid of the ultrapure water and the nitrogen gas, or more specifically, a fluid in which the ultrapure water is atomized by the nitrogen gas is generated. The fluid in the flow path 53 does not yet contain the IPA gas.

After that, the mixed fluid discharged from the outlet 53O of the flow path 53, and the IPA gas discharged from the outlet 54O of the flow path 54 are mixed at a position (a second mixing position) under the nozzle 15 and above the substrate W. The jets of the mixed fluid reach the substrate W, and are used for cleaning. Note that the second mixing position is farther away from the outlet 51O than the first mixing position.

The shapes and the like of the nozzle 15 and the flow paths 51 to 54 are not limited to those shown in FIG. 5A. That is, the flow paths 51 to 54 are only required to be designed so that the ultrapure water discharged from the flow path 51 and the nitrogen gas discharged from the flow path 52 are mixed in the flow path 53 in the nozzle 15, and the mixed fluid discharged from the flow path 53 and the IPA gas discharged from the flow path 54 are mixed at a position under the nozzle 15, to generate a mixed fluid for cleaning.

Alternatively, the flow path 54 may not be provided. In that case, a nozzle that discharges the IPA gas is provided in addition to the nozzle 15, and the mixed fluid discharged from the flow path 53 and the IPA gas may be mixed under the nozzle 15.

With the nozzle 15 having such a configuration, the IPA gas can be mixed with the mixed fluid of the ultrapure water and the nitrogen gas, without being greatly affected by the pressure and the flow rate of the nitrogen gas.

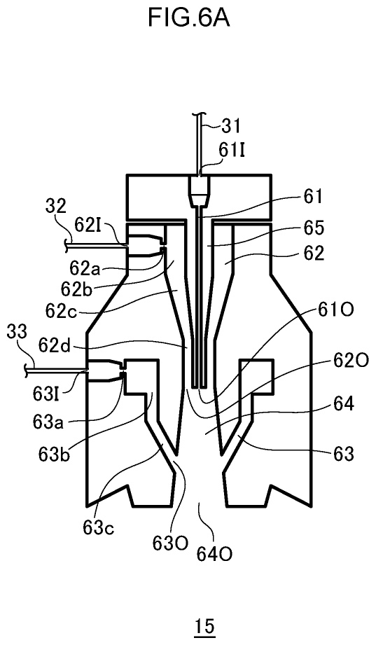

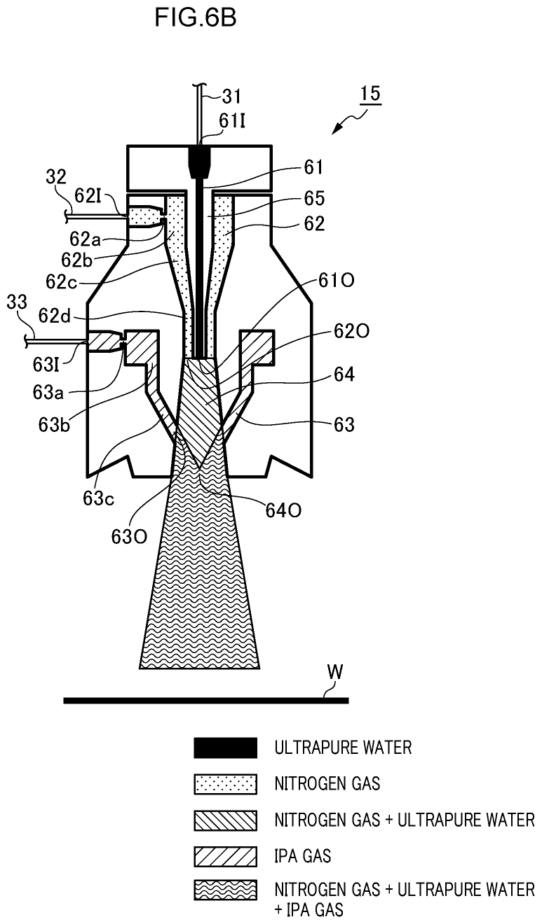

FIG. 6A is a schematic cross-sectional view of a nozzle 15 that is a modification of the nozzle shown in FIG. 4A. FIG. 6B is a diagram schematically illustrating states in which a fluid flows in the nozzle 15 shown in FIG. 6A. This nozzle 15 mixes the ultrapure water and the nitrogen gas in the nozzle 15, and also mixes the mixed fluid and the IPA gas in the nozzle 15.

The nozzle 15 includes a flow path 61 through which the ultrapure water passes, a flow path 62 through which the nitrogen gas passes, a flow path 63 through which the IPA gas passes, and a flow path 64 through which a mixed fluid of the ultrapure water, the nitrogen gas, and the IPA gas flows. The flow path 61 and the flow path 62 are separated from each other by a sidewall 65 in the nozzle 15. The configurations of the flow paths 61 and 62 are similar to those of the flow paths 51 and 52 shown in FIG. 5A, and therefore, detailed explanation thereof is not made herein.

The flow path 63 includes a horizontal portion 63a, an upper portion 63b, and a lower portion 63c. The horizontal portion 63a extends in a horizontal direction from the side surface of the nozzle 15, and reaches the side surface of the upper portion 63b. Outside the flow path 64, the upper portion 63b and the lower portion 63c of the flow path 63 are located concentrically with respect to the flow path 64, and horizontal cross-sections thereof are substantially annular. The upper portion 63b extends in a vertical direction. The bottom portion of the lower portion 63c is inclined toward the flow path 64. An outlet 63O of the lower portion 63c is joined to the flow path 64.

An inlet 63I of the flow path 63 is open toward the side of the outer surface of the nozzle 15, and the outlet 63O of the flow path 63 is provided inside the nozzle 15. The IPA gas supply pipe 33 is connected to the inlet 63I, which is one end of the horizontal portion 63a, and the IPA gas is supplied into the flow path 63. The IPA gas then exits from the outlet 63O of the flow path 63.

The flow path 64 is located under the flow path 61 and the flow path 62. The upper end of the flow path 63 is joined to the flow path 61 and the flow path 62. The flow path 64 is joined to the flow path 63 at a position between the upper end and the lower end. The flow path 64 extends in a vertical direction, and its lower end reaches the lower surface of the nozzle 15. The flow path 64 has a substantially circular cross-section in a horizontal direction. Also, the flow path 64 spreads out wide toward the end, and the diameter is larger at a portion closer to the lower surface.

At the upper end of the flow path 64, the ultrapure water flows in from the flow path 61, and the nitrogen gas flows in from the flow path 62. Further, the IPA gas flows into the flow path 64 from the flow path 63, and the IPA gas is further mixed with a mixed fluid of the ultrapure water and the nitrogen gas. A mixed fluid of the ultrapure water, the nitrogen gas, and the IPA gas then exits from an outlet 64O that is the lower end of the flow path 64.

In the nozzle 15 having the above configuration, the ultrapure water discharged from an outlet 61O of the flow path 61, and the nitrogen gas discharged from an outlet 62O of the flow path 62 are mixed at an upper portion (a first mixing position) of the flow path 63. As a result, a mixed fluid of the ultrapure water and the nitrogen gas, or more specifically, a fluid in which the ultrapure water is atomized by the nitrogen gas is generated. The fluid at this point of time does not yet contain the IPA gas.

After that, the IPA gas discharged from the outlet 63O of the flow path 63 further flows into the flow path 64, and the IPA gas is mixed with the mixed fluid of the ultrapure water and the nitrogen gas at a predetermined position (a second mixing position) in the flow path 64. The jets of this mixed fluid exit from the outlet 64O, which is the lower end of the flow path 64, then reach the substrate W, and are used for cleaning. Note that the second mixing position is farther away from the outlet 61O than the first mixing position.

The shapes and the like of the nozzle 15 and the flow paths 61 to 64 are not limited to those shown in FIG. 6A. That is, the flow paths 61 to 64 are only required to be designed so that the ultrapure water discharged from the flow path 61 and the nitrogen gas discharged from the flow path 62 are mixed to generate a mixed fluid in the flow path 64, and the mixed fluid and the IPA gas discharged from the flow path 63 are mixed to generate a mixed fluid for cleaning in the flow path 64. In other words, the flow paths 61 and 62 are only required to be joined to the flow path 64 at a certain position, and the flow path 63 is only required to be joined to the flow path 64 at a position on the downstream side thereof.

Although three examples of the nozzle 15 have been described above, the modes of cleaning fluid supplies are not limited to them. For example, on the upstream side of the nozzle 15, a mixed fluid in which the ultrapure water and the nitrogen gas are mixed may be supplied to the nozzle 15. Further, gaseous IPA may be further mixed with the mixed fluid inside the nozzle 15 (or on the downstream side of the nozzle 15). Alternatively, on the upstream side of the nozzle 15, a mixed fluid in which the ultrapure water and the nitrogen gas are mixed may be supplied to the nozzle 15. Further, a mixed fluid in which gaseous IPA is mixed with the mixed fluid may be supplied to the nozzle 15. However, to supply the cleaning fluid to the substrate W with sufficient force, it is desirable to perform mixing in the nozzle 15 or on the downstream side of the nozzle 15.

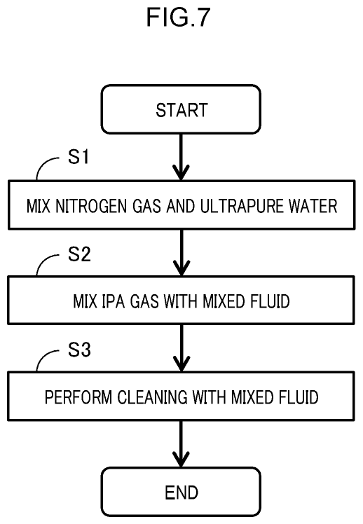

FIG. 7 is a substrate cleaning process chart according to an embodiment. First, the ultrapure water and the nitrogen gas are mixed (step S1). It can also be said that the substrate cleaning device 10 includes a first mixing means for mixing the ultrapure water and the nitrogen gas. This mixing may be performed before the ultrapure water and the nitrogen gas enter the nozzle 15, may be performed in the nozzle 15 (FIGS. 5B and 6B, for example), or may be performed after the ultrapure water and the nitrogen gas exit the nozzle 15 (FIG. 4B, for example).

After that, the IPA gas is mixed with the fluid (a first mixed fluid) generated in step S1 (step S2). It can also be said that the substrate cleaning device 10 includes a second mixing means for mixing the first mixed fluid and the IPA gas. This mixing is only required to be performed on the downstream of the mixing performed in step S1, and may be performed before the mixed fluid and the IPA gas enter the nozzle 15, may be performed in the nozzle 15 (FIG. 6B, for example), or may be performed after the mixed fluid and the IPA gas exit the nozzle 15 (FIGS. 4B and 5B, for example).

The jets of the fluid (a second mixed fluid) generated in step S2 are then supplied onto the surface of the substrate W, and the substrate W is cleaned (step S3).

As described above, in this embodiment, IPA gas is used, instead of liquid IPA. As the IPA in a gaseous state is made to pass through the filter 3F (FIG. 3), Fe-based fine particles and the like dissolved from a SUS container can be removed. Thus, back contamination is prevented, and cleaning performance is improved.

Also, in this embodiment, the ultrapure water and the nitrogen gas are first mixed, and then IPA is mixed with the resultant fluid. As the ultrapure water and the nitrogen gas are mixed beforehand, the ultrapure water is atomized. Accordingly, the total surface area of the ultrapure water becomes larger, and more IPA gas is uniformly dissolved in the ultrapure water. Thus, the surface tension of the ultrapure water can be reduced. As a result, when the cleaning fluid is supplied onto the substrate W, splashes not along the substrate surface can be reduced, and a radial flow along the substrate surface can be increased. Thus, cleaning performance is increased.

In the embodiment described above, the ultrapure water is merely an example of a treatment liquid, and a liquid containing carbon dioxide gas (pure water containing carbon dioxide gas, for example) can also be used as a treatment liquid, for example. As a liquid containing carbon dioxide gas is used, static charge of the substrate W can be prevented. However, IPA also has an antistatic effect, and therefore, the amount of carbon dioxide gas can be small. Further, there is a known example in which a liquid containing carbon dioxide gas corrodes a certain kind of wiring material. Therefore, instead of a liquid containing carbon dioxide gas, diluted ammonia water (pure water containing ammonia gas, for example) that also has an antistatic effect can also be used as a treatment liquid. The use of diluted ammonia water can prevent static charge of the substrate W. However, since IPA also has an antistatic effect, the amount of ammonia gas can be small.

Also, the nitrogen gas is merely an example of an inert gas, and some other inert gas may be used. Alternatively, in a case where the possibility of oxidation of a material exposed through the substrate surface by oxygen in the air is low, for example, compressed dry air (CDA) or the like can be used as an alternative to the inert gas. Further, the IPA gas is merely an example of a surface tension reducing gas, and any appropriate gas that reduces the surface tension of a treatment liquid, like various alcohols such as methanol, can be used as the surface tension reducing gas.

The above embodiments are disclosed for enabling those with ordinary knowledge in the technical field of the present invention to carry out the present invention. Various modifications of the above embodiments should be obvious to those skilled in the art, and the technical ideas of the present invention can be applied to other embodiments. Therefore, the present invention is not limited to the above embodiments, and should be construed as including a wider technical scope based on the technical ideas defined by the claims.

1. A substrate cleaning device comprising a nozzle that comprises:
a first supply port connected to a treatment liquid supplier configured to supply a treatment liquid;
a second supply port connected to a gas supplier configured to supply a gas;
a third supply port connected to a surface tension reducing gas supplier configured to supply a surface tension reducing gas for reducing surface tension of the treatment liquid;
a first discharge port configured to discharge the treatment liquid;
a second discharge port configured to discharge the gas, so as to mix the gas and the treatment liquid discharged from the first discharge port to generate a first mixed fluid at a first mixing position; and
a third discharge port configured to discharge the surface tension reducing gas, so as to mix the first mixed fluid and the surface tension reducing gas to generate a second mixed fluid at a second mixing position, the second mixing position being farther away from the first discharge port than the first mixing position,
wherein the substrate cleaning device is configured to clean a substrate with jets of the second mixed fluid.

2. A substrate cleaning device comprising a nozzle in which a first flow path, a second flow path and a third flow path are provided,
the first flow path being connected to a treatment liquid supplier configured to supply a treatment liquid;
the second flow path being connected to a gas supplier configured to supply a gas; and
the third flow path being configured to a surface tension reducing gas supplier configured to supply a surface tension reducing gas for reducing surface tension of the treatment liquid,
wherein the first flow path, the second flow path, and the third flow path are configured such that the treatment liquid discharged from the first flow path and the gas discharged from the second flow path are mixed at a first mixing position to generate a first mixed fluid, and the first mixed fluid and the surface tension reducing gas discharged from the third flow path are mixed at a second mixing position to generate a second mixed fluid, the second mixing position being located on a downstream side of the first mixing position in a flow of the first mixed fluid, and
the substrate cleaning device is configured to clean a substrate with jets of the second mixed fluid.

3. A substrate cleaning device comprising a nozzle in which a first flow path, a second flow path, a third flow path and a fourth path are provided,
the first flow path being connected to a treatment liquid supplier configured to supply a treatment liquid;
the second flow path being connected to a gas supplier configured to supply a gas;
the third flow path being connected to a surface tension reducing gas supplier configured to supply a surface tension reducing gas for reducing surface tension of the treatment liquid; and
the fourth flow path being joined to the first flow path and the second flow path, a first mixed fluid flowing through the fourth flow path, the first mixed fluid being a mixture of the treatment liquid and the gas,
wherein the third flow path and the fourth flow path are configured such that the first mixed fluid discharged from the fourth flow path and the surface tension reducing gas discharged from the third flow path are mixed to generate a second mixed fluid, and
the substrate cleaning device is configured to clean a substrate with jets of the second mixed fluid.

4. A substrate cleaning device comprising a nozzle that comprises in the nozzle in which a first flow path, a second flow path, a third flow path and a fourth path are provided,
the first flow path being connected to a treatment liquid supplier configured to supply a treatment liquid;
the second flow path being connected to a gas supplier configured to supply a gas;
the third flow path being connected to a surface tension reducing gas supplier configured to supply a surface tension reducing gas for reducing surface tension of the treatment liquid; and
the fourth flow path being joined to the first flow path, the second flow path, and the third flow path,
wherein the first to fourth flow paths are configured such that the treatment liquid discharged from the first flow path and the gas discharged from the second flow path are mixed at a first mixing position to generate a first mixed fluid in the fourth flow path, and the first mixed fluid and the surface tension reducing gas discharged from the third flow path are mixed at a second mixing position to generate a second mixed fluid in the fourth flow path, the second mixing position being located on a downstream side of the first mixing position in a flow of the first mixed fluid, and
the substrate cleaning device is configured to clean a substrate with jets of the second mixed fluid.

5. The substrate cleaning device according to claim 1, further comprising:
a gasifier configured to gasify a surface tension inhibitor in a liquid state, to generate the surface tension reducing gas.

6. The substrate cleaning device according to claim 5, wherein the gasifier is configured to gasify the surface tension inhibitor in a liquid state by an injection technique, to generate the surface tension reducing gas.

7. The substrate cleaning device according to claim 5, wherein the gasifier is of a baking type, of a bubbling type, or a vaporizer.

8. The substrate cleaning device according to claim 1, further comprising:
a filter through which the surface tension reducing gas passes,
wherein the surface tension reducing gas having passed through the filter is mixed with the first mixed fluid.

9. The substrate cleaning device according to claim 1, further comprising:
a cleaning fluid supplier configured to supply the treatment liquid to the nozzle at 200 to 400 ml/min.

10. The substrate cleaning device according to claim 1, further comprising:
a cleaning fluid supplier that supplies the gas to the nozzle at 100 to 200 SLM.

11. The substrate cleaning device according to claim 1, wherein
the treatment liquid is ultrapure water or carbon-dioxide-containing water,
the gas is an inert gas or dry air, and
the surface tension reducing gas is an IPA gas.

12. The substrate cleaning device according to claim 11, wherein the inert gas is a nitrogen gas.

13. The substrate cleaning device according to claim 12, wherein a concentration of the IPA gas in the second mixed fluid, or a total concentration of the IPA gas and the nitrogen gas in the second mixed fluid is 10 to 30%.

14. A substrate processing apparatus comprising:
a substrate polishing device configured to polish a substrate; and
the substrate cleaning device according to claim 1, configured to clean the polished substrate.

15. A substrate cleaning method comprising:
mixing a treatment liquid and a gas to generate a first mixed fluid;
mixing a surface tension reducing gas for reducing surface tension of the treatment liquid and the first mixed fluid to generate a second mixed fluid, after the first mixed fluid is generated; and
cleaning a substrate by emitting jets of the second mixed fluid onto the substrate.

16. A nozzle used for a substrate cleaning device, a first flow path, a second flow path, a third flow path and a fourth flow path are provided in the nozzle,
the first flow path comprising a first inlet and a first outlet, the first inlet being open toward an outer surface of the nozzle, the first outlet being provided inside the nozzle;
the second flow path that comprising a second inlet and a second outlet, the second inlet being open toward the outer surface of the nozzle, the second outlet being provided inside the nozzle;
the third flow path that comprising a third inlet and a third outlet, the third inlet being open toward the outer surface of the nozzle, the third outlet being open toward a bottom surface of the nozzle; and
the fourth flow path that comprising a fourth inlet and a fourth outlet, the fourth inlet being joined to the first outlet and the second outlet inside the nozzle, the fourth outlet being open toward the bottom surface of the nozzle,
wherein the fourth flow path is located substantially at a center of the nozzle, and a diameter of the fourth flow path at least in a vicinity of the fourth outlet is larger at a location closer to the bottom surface of the nozzle, and
the third flow path is located radially outside the nozzle with respect to the third flow path, and at least a portion of the third flow path in a vicinity of the third outlet is more inclined to the center of the nozzle at a location closer to the bottom surface of the nozzle.
